(19) United States
(12) Patent Application Publication
(10) Pub. No.: US 2025/0300029 A1
(43) Pub. Date: Sep. 25, 2025

(54) PACKAGE SUBSTRATE AND SEMICONDUCTOR PACKAGE

(71) Applicant: Samsung Electronics Co., Ltd., Suwon-si (KR)

(72) Inventor: Jaehyuk Choi, Suwon-si (KR)

(21) Appl. No.: 19/052,501

(22) Filed: Feb. 13, 2025

(30) Foreign Application Priority Data
Mar. 19, 2024 (KR) 10-2024-0037741

(51) Int. Cl. H01L 23/14; H01L 23/31; H01L 23/498

(52) U.S. Cl. CPC H01L 23/145; H01L 23/49894; H01L 23/3121

(57) ABSTRACT

A package substrate may include a core layer including at least one woven prepreg having woven fiber arrays; an upper insulation layer including a first unidirectional prepreg and a second unidirectional prepreg stacked on the package substrate; a lower insulation layer including a third unidirectional prepreg and a fourth unidirectional prepreg stacked on the package substrate; and inner wirings, wherein the first unidirectional prepreg includes first unidirectional fiber arrays having a first angle relative to a first direction, and the second unidirectional prepreg includes second unidirectional fiber arrays having a second angle relative to the first direction, and wherein the third unidirectional prepreg includes third unidirectional fiber arrays having a third angle relative to the first direction, and the fourth unidirectional prepregs includes fourth unidirectional fiber arrays having a fourth angle relative to the first direction.

### PRIORITY STATEMENT

The present application claims priority under 35 U.S.C. § 119 to Korean Patent Application No. 10-2024-0037741, filed on Mar. 19, 2024 in the Korean Intellectual Property Office (KIPO), the contents of which are herein incorporated by reference in their entirety.

### BACKGROUND

The present disclosure relates to a package substrate capable of preventing warpage. More particularly, the present disclosure relates to a package substrate providing a prepreg having a plurality of unidirectional fibers and a semiconductor package including the same.

A semiconductor package includes diverse components such as a package substrate, a semiconductor chip, a molding member, a solder ball, etc., and warpage may occur due to differences in coefficients of thermal expansion between the diverse components of the semiconductor package. In the related arts, a package substrate including a woven prepreg (PPG) with high symmetry may be used to prevent warpage of a semiconductor package. However, the woven prepreg cannot prevent warpage of various shapes due to the high symmetry of the woven prepreg. In particular, the shape of warpage has become more complex as the structure of the semiconductor package has become more complex, and thus, a package substrate capable of preventing warpage of various shapes may be desired.

### SUMMARY

Example embodiments provide a package substrate capable of preventing a warpage.

Example embodiments provide a semiconductor package including the package substrate.

According to example embodiments, a package substrate includes a core layer providing a first surface and an opposing second surface, the core layer including at least one woven prepreg having a plurality of woven fiber arrays intersecting or overlapping each other; an upper insulation layer including a first unidirectional prepreg and a second unidirectional prepreg sequentially stacked on the first surface of the core layer; a lower insulation layer including a third unidirectional prepreg and a fourth unidirectional prepreg sequentially stacked on the second surface of the core layer; and a plurality of inner wirings in the core layer, the upper insulation layer, and the lower insulation layer and electrically connected to each other, wherein the first unidirectional prepreg includes a plurality of first unidirectional fiber arrays having a first angle relative to a first direction, and the second unidirectional prepreg includes a plurality of second unidirectional fiber arrays having a second angle relative to the first direction, and wherein the third unidirectional prepreg includes a plurality of third unidirectional fiber arrays having a third angle relative to the first direction, and the fourth unidirectional prepregs includes a plurality of fourth unidirectional fiber arrays having a fourth angle relative to the first direction.

According to example embodiments, a package substrate includes a core layer providing a first surface and an opposing second surface, the core layer including at least one woven prepreg having a plurality of woven fiber arrays intersecting or overlapping each other; a plurality of conductive connection members including a plurality of first inner wirings in the core layer, a plurality of first upper wirings on the first surface of the core layer, and a plurality of first lower wirings on the second surface of the core layer; an upper insulation layer including a first unidirectional prepreg and a second unidirectional prepreg sequentially stacked on the first surface of the core layer; a plurality of second inner wirings in the upper insulation layer and electrically connected to the plurality of conductive connection members; a lower insulation layer including a third unidirectional prepreg and a fourth unidirectional prepreg sequentially stacked on the second surface of the core layer; and a plurality of third inner wirings in the lower insulation layer and electrically connected to the conductive connection members, wherein the first unidirectional prepreg includes a plurality of first unidirectional fiber arrays having a first angle relative to a first direction, and the second unidirectional prepreg includes a plurality of second unidirectional fiber arrays having a second angle relative to the first direction, and wherein the third unidirectional prepreg includes a plurality of third unidirectional fiber arrays having a third angle relative to the first direction, and the fourth unidirectional prepregs includes a plurality of fourth unidirectional fiber arrays having a fourth angle relative to the first direction.

According to example embodiments, a semiconductor package includes a package substrate including a core layer providing at least one woven prepreg that has a plurality of woven fiber arrays, an upper insulation layer including a plurality of upper prepregs sequentially stacked on a first surface of the core layer, and a lower insulation layer including a plurality of lower prepregs sequentially stacked on a second surface of the core layer opposite to the first surface of the core layer, a plurality of inner wirings provide in the package substrate and electrically connected to each other, a plurality of upper substrate pads electrically connected to the plurality of inner wirings, and a plurality of lower substrate pads electrically connected to the plurality of inner wirings; at least one semiconductor chip mounted on the package substrate; and a molding member on the package substrate to at least partially cover the at least one semiconductor chip, wherein the plurality of upper prepregs includes a first unidirectional prepreg having a plurality of first unidirectional fiber arrays having a first angle relative to a first direction and a second unidirectional prepregs having a plurality of second unidirectional fiber arrays having a second angle relative to the first direction, and wherein the plurality of lower prepregs includes a third unidirectional prepreg having a plurality of third unidirectional fiber arrays having a third angle relative to the first direction and a fourth unidirectional prepreg includes a fourth unidirectional prepreg having a plurality of fourth unidirectional fiber arrays having a fourth angle relative to the first direction.

According to example embodiments, a package substrate may include a core layer including at least one woven prepreg, an upper insulation layer stacked on a first surface of the core layer and including a plurality of first unidirectional prepregs, and a lower insulation layer stacked on a second surface of the core layer and including a plurality of second unidirectional prepregs.

Each of the plurality of first unidirectional prepregs and each of the plurality of second unidirectional prepregs may include a plurality of unidirectional fiber arrays extending different directions between each other. The plurality of unidirectional fiber arrays may have different angles from a predetermined direction, respectively.

Accordingly, the package substrate may improve the warpage of the semiconductor package by combining the different angles of the unidirectional prepregs to induce a warpage opposite to the warpage of the semiconductor package. Therefore, the package substrate may prevent the warpage having various shapes.

### BRIEF DESCRIPTION OF THE DRAWINGS

FIG. 1 is a cross-sectional side view illustrating a semiconductor package in accordance with example embodiments.

FIG. 2 is a cross-sectional side view illustrating a package substrate for the semiconductor package in FIG. 1 in accordance with example embodiments.

FIG. 3 is a plan view illustrating a woven prepreg of the package substrate in FIG. 2 in accordance with example embodiments.

FIG. 4 is an exploded view illustrating unidirectional prepregs of the package substrate in FIG. 2 in accordance with example embodiments.

FIG. 5 is a graph illustrating changes in tensile stiffness according to an angle change of the woven prepreg and an angle change of the unidirectional prepreg in accordance with example embodiments.

FIGS. 6A to 6E show simulation data illustrating warpages of unidirectional prepregs according to example embodiments in accordance with example embodiments.

FIG. 7 is a cross-sectional side view illustrating a semiconductor package in accordance with example embodiments.

### DETAILED DESCRIPTION

Advantages and features of the present disclosure, and a method of achieving the advantages and features will become apparent with reference to embodiments described below in detail together with the accompanying drawings. However, the embodiments of the present disclosure are not limited to the example embodiments as disclosed herein, but may be implemented in various different forms. Thus, these embodiments are set forth only to make the present disclosure, and to inform the scope of the present disclosure to those of ordinary skill in the technical field to which the present disclosure belongs, and the present disclosure is only defined by the scope of the claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will also be understood that when a first element or layer is referred to as being present “on” a second element or layer, the first element may be disposed directly on the second element or may be disposed indirectly on the second element with a third element or layer being disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers. It will be understood that when an element or layer is referred to as being “connected to”, or “coupled to” another element or layer, it may be directly connected to or coupled to another element or layer, or one or more intervening elements or layers therebetween may be present. In addition, it will also be understood that when an element or layer is referred to as being “between” two elements or layers, it may be the only element or layer between the two elements or layers, or one or more intervening elements or layers therebetween may also be present.

In addition, it will also be understood that when an element or layer is referred to as being “between” two elements or layers, it may be the only element or layer between the two elements or layers, or one or more intervening elements or layers therebetween may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

As used herein, “embodiments”, “examples”, “aspects”, and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

As used herein, an element or region that is “covering” or “surrounding” or “filling” another element or region may completely or partially cover or surround or fill the other element or region.

The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Hereinafter, example embodiments of the present disclosure will be explained in detail with reference to the accompanying drawings.

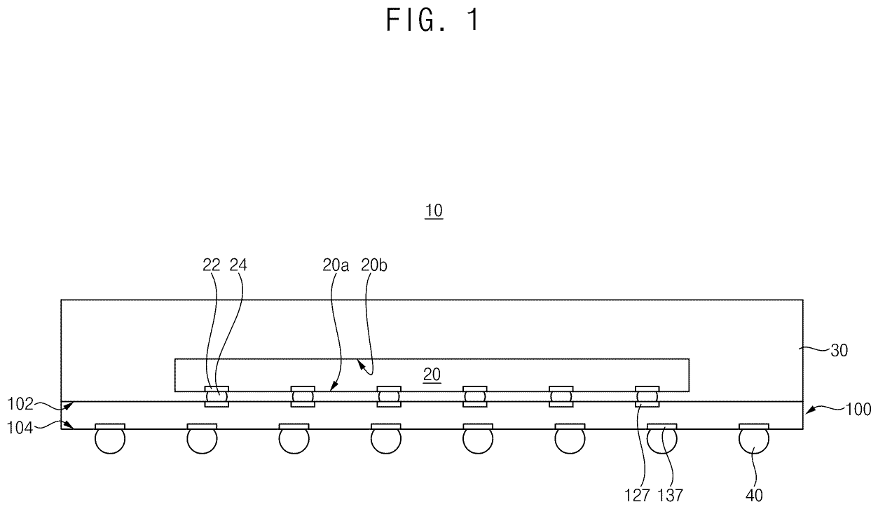

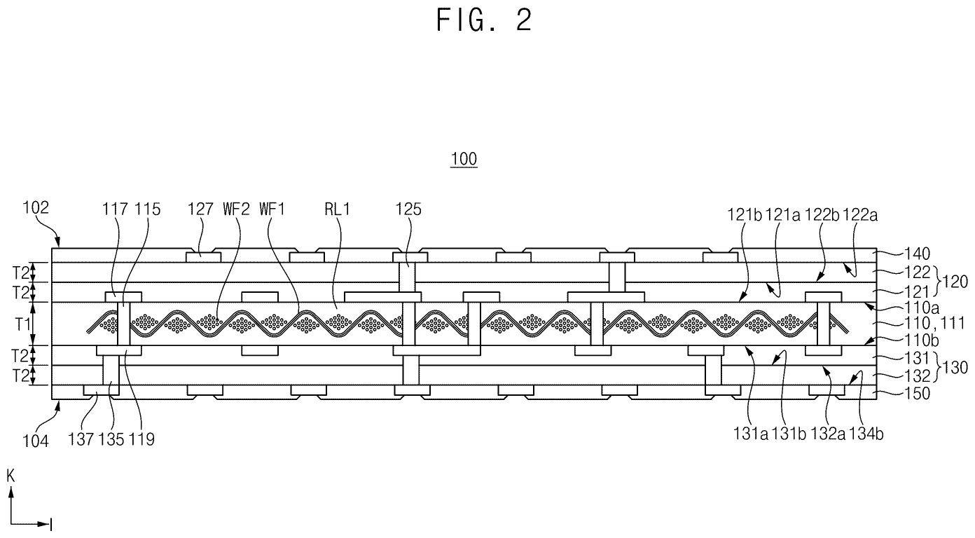

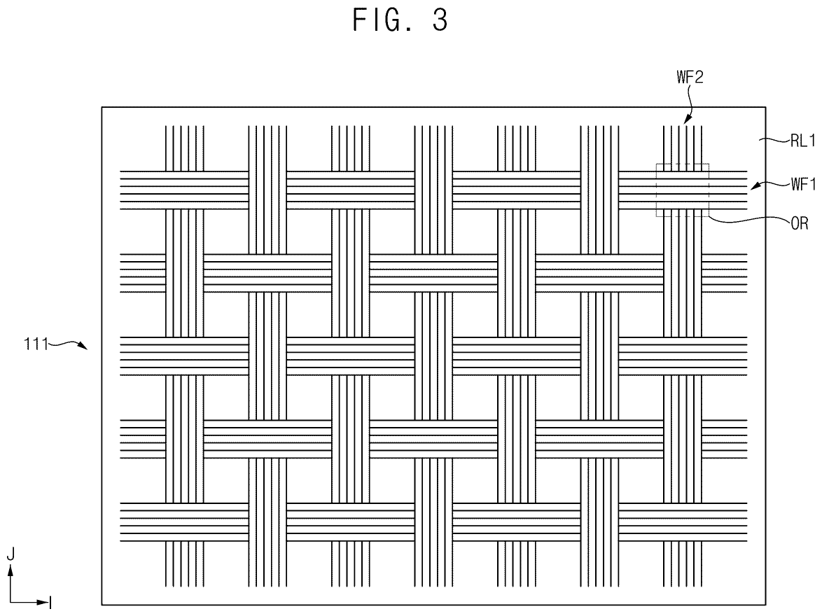

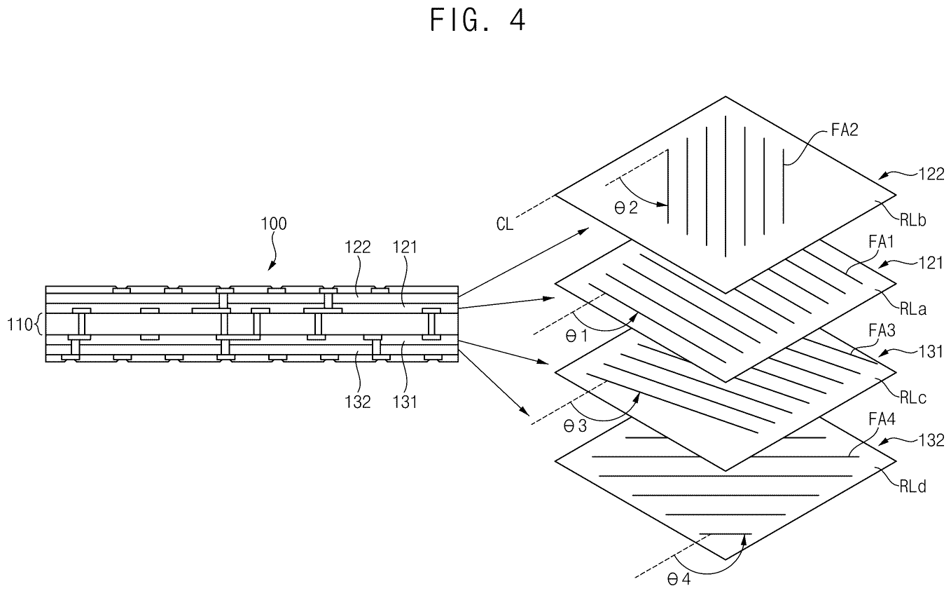

FIG. 1 is a cross-sectional side view illustrating a semiconductor package in accordance with example embodiments. FIG. 2 is a cross-sectional side view illustrating a package substrate of the semiconductor package in FIG. 1. FIG. 3 is a plan view illustrating a woven prepreg of the package substrate in FIG. 2. FIG. 4 is an exploded view illustrating unidirectional prepregs of the package substrate in FIG. 2.

Referring to FIG. 1, a semiconductor package 10 may include a package substrate 100 having a first surface 102 and an opposing second surface 104 (i.e., facing each other), at least one semiconductor chip 20 mounted on the first surface 102 of the package substrate 100, a molding member 30 provided on the first surface 102 of the package substrate 100 and at least partially covers the at least one semiconductor chip 20, and a plurality of external connection members 40 disposed on the second surface 104 of the package substrate 100. For example, the molding member 30 may include an epoxy molding compound (EMC).

In some embodiments, the package substrate 100 may include a plurality of upper substrate pads 127 disposed on the first surface 102 to be at least partially exposed from the first surface 102 (i.e., at least a portion of the upper substrate pads 127 is free from the first surface 102) and a plurality of lower substrate pads 137 disposed on the second surface 104 to be at least partially exposed from the second surface 104 (i.e., at least a portion of the lower substrate pads 137 is free from the second surface 104). For example, the package substrate 100 may be a multilayer circuit board including a core layer having at least one woven prepreg which is disposed in a center, a plurality of insulation layers having a plurality of unidirectional prepregs stacked sequentially on an upper surface and a lower surface of the core layer, and a plurality of inner wires disposed within the core layer and the plurality of insulation layers to be electrically connected to each other (see, e.g., FIGS. 2 to 4). For example, the woven prepreg may include a plurality of woven fiber arrays, which are disposed at 0 degrees or 90 degrees to intersect each other, and a resin in which the plurality of woven fiber arrays are impregnated. Additionally, the unidirectional prepreg may include a plurality of unidirectional fiber arrays extending in a first direction and a resin in which the plurality of unidirectional fiber arrays are impregnated.

In some embodiments, the at least one semiconductor chip 20 may include a front surface 20a and a backside surface 20b facing each other, a plurality of chip pads 22 disposed on the front surface 20a, and a plurality of conductive connection members 24 respectively disposed on the plurality of chip pads 22. For example, the at least one semiconductor chip 20 may be mounted on the first surface 102 of the package substrate 100 via the plurality of conductive connection members 24 respectively provided between the plurality of chip pads 22 and the plurality of upper substrate pads 127 of the package substrate 100.

Although the figures illustrate the at least one semiconductor chip 20 as a single semiconductor mounted in a flip chip manner, it will be appreciated that this is an example, so the present disclosure is not limited thereto. Accordingly, the number, size, arrangement, mounting method, etc. of the at least one semiconductor chip 20 may be varied.

In some embodiments, the plurality of external connection members 40 may be provided on the plurality of lower substrate pads 137 of the package substrate 100, respectively. For example, the plurality of external connection members 40 may include a conductive material and serve to electrically connect the semiconductor package 10 to an external device on which the semiconductor package 10 is mounted.

Hereinafter, the package substrate 100 in accordance with example embodiments will be described in detail.

Referring to FIGS. 2 to 4, according to some embodiments, the package substrate 100 of the semiconductor package 10 may include a core layer 110 providing a first surface 110a and a second surface 110b and having at least one woven prepreg 111 therein. The package substrate 100 may further include an upper insulation layer 120 having a first unidirectional prepreg 121 and a second unidirectional prepreg 122 sequentially stacked on the first surface 110a of the core layer 110, and a lower insulation layer 130 having a third unidirectional prepreg 131 and a fourth unidirectional prepreg 132 sequentially stacked on the second surface 110b of the core layer 110.

Additionally, according to some embodiments, the package substrate 100 may include a plurality of inner wirings 115, 117, 119, 125, 135 provided in the core layer 110, the upper insulation layer 120, and the lower insulation layer 130 and electrically connected to each other. The package substrate 100 may include a plurality of upper substrate pads 127 provided on the upper insulation layer 120 to be electrically connected to the plurality of inner wirings 125 and a plurality of lower substrate pads 137 provided on the lower insulation layer 130 to be electrically connected to the plurality of inner wirings 135. For example, according to some embodiments, the plurality of inner wirings 115, 117, 119, 125, 135, the plurality of upper substrate pads 127, and the plurality of lower substrate pads 137 may include a metallic material such as copper (Cu).

Further, according to some embodiments, the package substrate 100 may include an upper cover layer 140 provided on the upper insulation layer 120 which at least partially exposes the plurality of upper substrate pads 127 and a lower cover layer 150 provided on the lower insulation layer 130 which at least partially exposes the plurality of lower substrate pads 137. For example, according to some embodiments, the upper cover layer 140 and the lower cover layer 150 may include a solder resist.

In some embodiments, the core layer 110 may include at least one woven prepreg 111 that provides a plurality of woven fiber arrays WF1 and WF2 intersecting and/or overlapping each other and a first resin layer RL1 at least partially surrounding the plurality of woven fiber arrays WF1 and WF2. For example, according to some embodiments, the core layer 110 may be provided in a generally center portion of the package substrate 100 and may be a layer having a relatively high stiffness in order to help prevent warpage of the package substrate 100. Additionally, according to some embodiments, the core layer 110 may include a plurality of first inner wires 115 provided therein, a plurality of first upper wires 117 disposed on a first surface 110a of the core layer 110 and electrically connected to the plurality of first inner wires 115, and a plurality of first lower wires 119 disposed on a second surface 110b of the core layer 110 and electrically connected to the plurality of first inner wires 115.

In some embodiments, the at least one woven prepreg 111 may have a first thickness T1. For example, the first thickness T1 may be in a range of about 30 μm to about 40 μm.

As shown in FIG. 3, according to some embodiments, the plurality of woven fiber arrays may include a plurality of first woven fiber arrays WF1 extending in a first horizontal direction (I direction) and a plurality of second woven fiber arrays WF2 extending in a second horizontal direction (J direction) that is perpendicular to the first horizontal direction (I direction). For example, according to some embodiments, the first woven fiber array WF1 and the second woven fiber array WF2 may include a plurality of fiber filaments adjacent to each other.

As used and described herein, a direction in which the plurality of first woven fiber arrays WF1 extends may be referred to as a first horizontal direction (I direction), and a horizontal direction orthogonal to the first horizontal direction (I direction) may be referred to as a second horizontal direction (J direction), and a direction orthogonal to the first horizontal direction and the second horizontal direction may be referred to as a vertical direction (K direction).

The plurality of first woven fiber arrays WF1 may be provided in the first resin layer RL1 to be spaced apart from each other in the first horizontal direction (I direction). Further, the plurality of second woven fiber arrays WF2 may be provided in the first resin layer RL1 to be spaced apart from each other in the second horizontal direction (J direction). For example, according to some embodiments, the plurality of first woven fiber arrays WF1 and the plurality of second woven fiber arrays WF2 may include reinforcement fibers such as glass fibers, carbon fibers, etc. Further, according to some embodiments, the first resin layer RL1 may include a thermosetting material, such as an epoxy resin, etc.

The plurality of first woven fiber arrays WF1 and the plurality of second woven fiber arrays WF2 may intersect and/or overlap each other. For example, the plurality of first woven fiber arrays WF1 may extend in the first horizontal direction (I direction) to alternately weave over and under the plurality of second woven fiber arrays WF2 in a regular repeated manner. The plurality of second woven fiber arrays WF2 may extend in the second horizontal direction (J direction) to alternately weave over and under the plurality of first woven fiber arrays WF1 in a regular repeated manner. Thus, according to some embodiments, the plurality of first woven fiber arrays WF1 and the plurality of second woven fiber arrays WF2 may form a plurality of overlapping regions (OR) when viewed in a plan view (for example, as illustrated in FIG. 3).

In some embodiments, the upper insulation layer 120 may include a first unidirectional prepreg 121 and a second unidirectional prepreg 122 sequentially stacked on the first surface 110a of the core layer 110. For example, according to some embodiments, the first unidirectional prepreg 121 and the second unidirectional prepreg 122 may be structures configured to help prevent warpage in a particular direction, for example, in the first horizontal direction (I direction), in the second horizontal direction (J direction), the vertical direction (K direction), and/or an angled direction relative to a reference extension line CL (see, e.g., FIG. 4).

Each of the first unidirectional prepreg 121 and the second unidirectional prepreg 122 may have a second thickness T2. In some embodiments, the second thickness T2 of the first and second unidirectional prepreg is less than the first thickness T1 of the at least one woven prepreg 111. For example, according to some embodiments, the second thickness T2 may be in a range of about 10 μm to about 20 μm.

As shown in FIG. 4, in some embodiments, the first unidirectional prepreg 121 may include a plurality of first unidirectional fiber arrays FA1 that have a first angle θ1 relative to a reference extension line CL extending in a predetermined direction, and a fourth resin layer RLa surrounding the plurality of first unidirectional fiber arrays FA1. The second unidirectional prepreg 122 may include a plurality of second unidirectional fiber arrays FA2 that have a second angle θ2 relative to the reference extension line CL and a fifth resin layer RLb surrounding the plurality of second unidirectional fiber arrays. For example, according to some embodiments, the reference extension line CL may be parallel to the first horizontal direction (I direction) or the second horizontal direction (J direction).

In some embodiments, the plurality of first unidirectional fiber arrays FA1 and the plurality of second unidirectional fiber arrays FA2 may include a plurality of fiber filaments adjacent to each other. For example, in some embodiments, the plurality of first unidirectional fiber arrays FA1 and the plurality of second unidirectional fiber arrays FA2 may include reinforcement fibers such as glass fibers, carbon fibers, etc. Further, the fourth resin layer RLa of the first unidirectional prepreg 121 and the fifth resin layer RLb of the second unidirectional prepreg 122 may include a thermosetting material, such as an epoxy resin, etc.

In some embodiments, the lower insulation layer 130 may include a third unidirectional prepreg 131 and a fourth unidirectional prepreg 132 sequentially stacked on the second surface 110b of the core layer 110. For example, according to some embodiments, the third unidirectional prepreg 131 and the fourth unidirectional prepreg 132 may be structures configured to prevent warpage in a particular direction, for example, in the first horizontal direction (I direction), in the second horizontal direction (J direction), and/or the vertical direction (K direction), and/or an angled direction relative to the reference extension line CL.

Each of the third unidirectional prepreg 131 and the fourth unidirectional prepreg 132 may have a second thickness T2. In some embodiments, the second thickness T2 of the third and fourth unidirectional prepreg 131, 132 is less than the first thickness T1 of the at least one woven prepreg 111. For example, according to some embodiments, the second thickness T2 may be in a range of about 10 μm to about 20 μm.

As further shown in FIG. 4, in some embodiments, the third unidirectional prepreg 131 may include a plurality of third unidirectional fiber arrays FA3 that have a third angle θ3 relative to the reference extension line CL, and a sixth resin layer RLc surrounding the plurality of third unidirectional fiber arrays FA3. The fourth unidirectional prepreg 132 may include a plurality of fourth unidirectional fiber arrays FA4 that have a fourth angle (θ4) relative to the reference extension line CL, and a seventh resin layer RLd surrounding the plurality of fourth unidirectional fiber arrays FA4.

In some embodiments, the plurality of third unidirectional fiber arrays FA3 and the plurality of fourth unidirectional fiber arrays FA4 may include a plurality of fiber filaments adjacent to each other. For example, in some embodiments, the plurality of third unidirectional fiber arrays FA3 and the plurality of fourth unidirectional fiber arrays FA4 may include reinforcement fibers such as glass fibers, carbon fibers, etc. Further, in some embodiments, the sixth resin layer RLc of the third unidirectional prepreg 131 and the resin layer seventh RLd of the fourth unidirectional prepreg 132 may include a thermosetting material, such as an epoxy resin, etc.

In some embodiments, the first to fourth angles (θ1, θ2, θ3, θ4) may be different angles relative to the reference extension line CL. For example, in some embodiments, the first angle (θ1) may be 90 degrees, the second angle (θ2) may be 45 degrees, the third angle (θ3) may be 285 degrees, and the fourth angle (θ4) may be 315 degrees.

In some embodiments, the first to third angles (θ1, θ2, θ3) may have the same angle with each other. For example, in some embodiments, the first, second, and third angles (θ1, θ2, θ3) may be 0 degrees, and the fourth angle (θ4) may be 90 degrees. Alternatively, in some embodiments, the first, second, and third angles (θ1, θ2, θ3) may be 90 degrees and the fourth angle (θ4) may be 0 degrees.

In some embodiments, the first angle (θ1), the third angle (θ3), and the fourth angle (θ4) may have the same angle. For example, in some embodiments, the first angle (θ1), the third angle (θ3), and the fourth angle (θ4) may be 315 degrees, and the second angle (θ2) may be 45 degrees. Alternatively, in some embodiments, the first angle (θ1), the third angle (θ3), and the fourth angle (θ4) may be 45 degrees, and the second angle (θ2) may be 315 degrees.

Since the first to fourth angles (θ1, θ2, θ3, θ4) are exemplary, the present inventive concept is not limited thereto. Accordingly, the sizes of the first to fourth angles (θ1, θ2, θ3, θ4) may be varied depending on a direction of warpage which occurs in the semiconductor package 10.

While the figures illustrate that the package substrate 100 includes the first to fourth unidirectional prepregs 121, 122, 131, 132, it will be appreciated that this is exemplary, so the present inventive concept is not limited thereto. Accordingly, the number of the first to fourth unidirectional prepregs 121, 122, 131, 132 may also be varied.

Hereinafter, experimental data for package substrate 100 in accordance with example embodiments will be described.

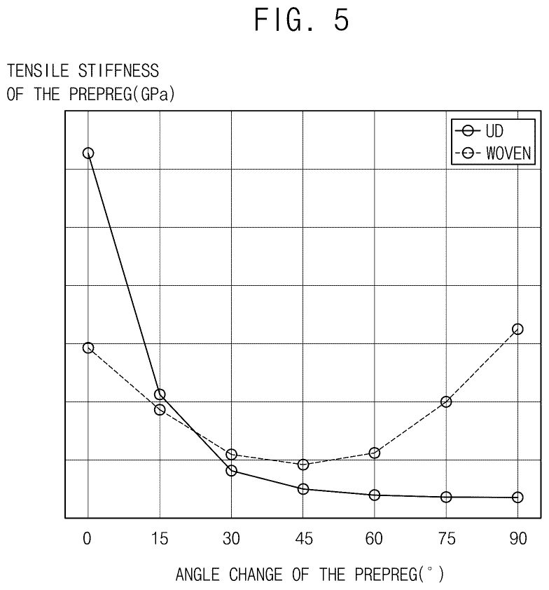

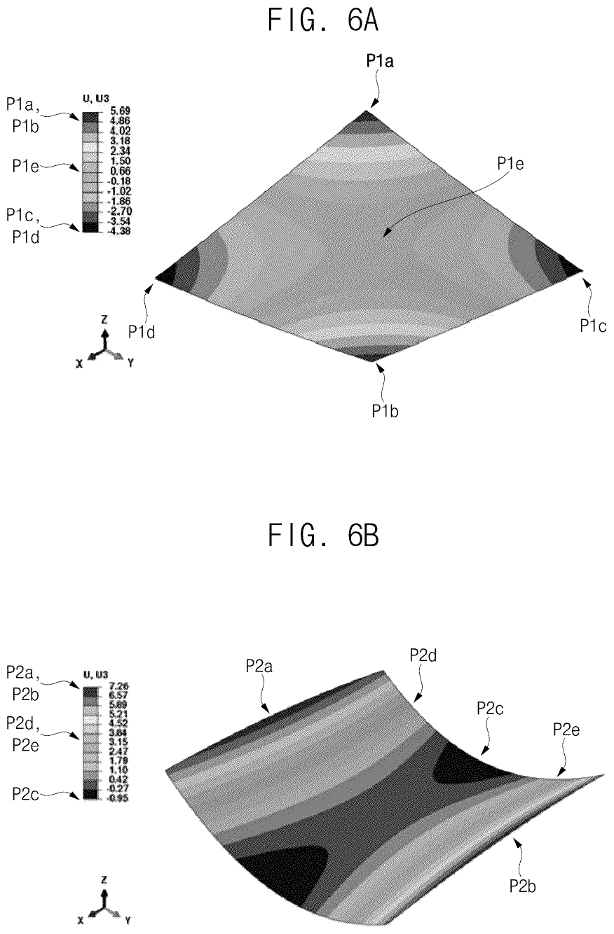

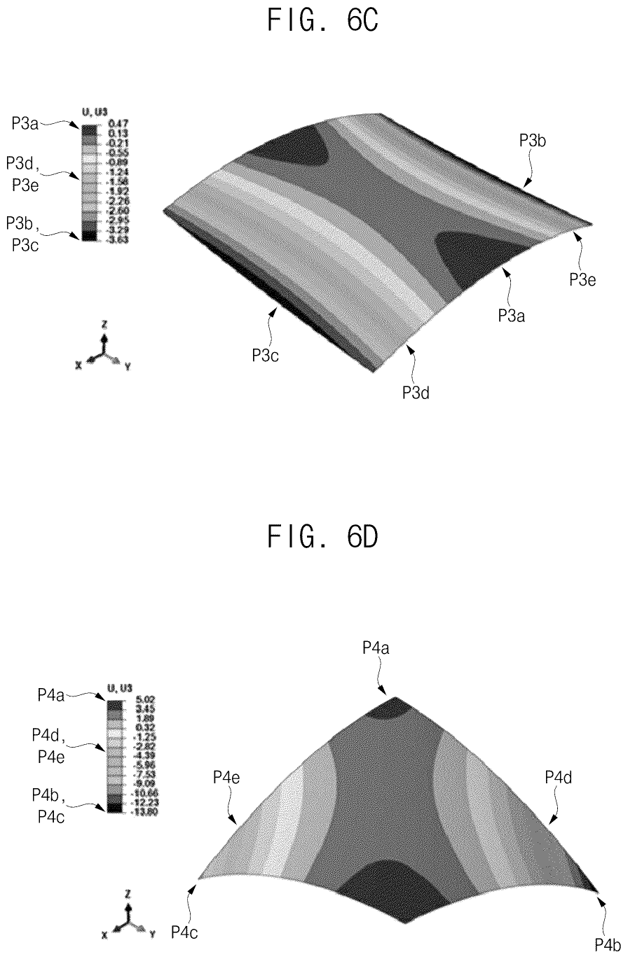

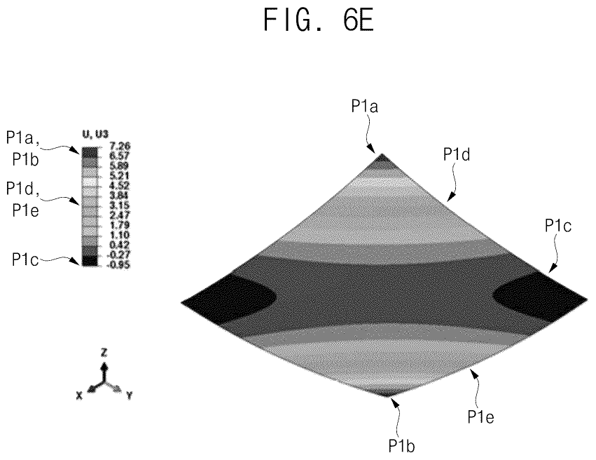

FIG. 5 is a graph illustrating changes in tensile stiffness according to an angle change of the woven prepreg and an angle change of the unidirectional prepreg. FIGS. 6A to 6E show simulation data illustrating warpages of unidirectional prepregs according to example embodiments.

The tensile stiffness data of a prepreg shown in FIG. 5 was determined by fixing a direction in which a force is applied at “0 degrees” and varying an angle of the prepreg being tested. In the graph of FIG. 5, “UD” may denote test results for unidirectional prepregs, and “WOVEN” may denote test results for woven prepregs. In the graph of FIG. 5, a horizontal axis may be an angle change of the prepreg, and a vertical axis may be the tensile stiffness of the prepreg according to the angle change of the prepreg.

Referring to FIG. 5, the unidirectional prepregs 121, 122, 131, 132 may have relatively greater tensile stiffness (i.e., compared to woven prepregs) in case that the unidirectional fibers inside are parallel to the direction of an applied force, i.e., when the stack angle is 0 degrees. In contrast, the unidirectional prepregs 121, 122, 131, 132 may have relatively less tensile stiffness (i.e., compared to woven prepregs) in case that the unidirectional fibers inside are perpendicular to the direction of the applied force, i.e., when the stack angle is 90 degrees.

The woven prepreg 111 may have a relatively less tensile stiffness (i.e., compared to unidirectional prepregs) when the stack angle is 45 degrees. In contrast, the woven prepreg 111 may have relatively greater tensile stiffness (i.e., compared to unidirectional prepregs) when the stack angle is 0 degrees or 90 degrees.

The unidirectional prepregs 121, 122, 131, 132 may have a relatively greater change in tensile stiffness (i.e., compared to woven prepregs) according to changes in the stack angle. In contrast, the woven prepreg 111 may have a relatively less change in tensile stiffness (i.e., compared to unidirectional prepregs) according to a change in the stack angle.

Referring to the simulation data in FIG. 6, the shape of the warpage in the plurality of unidirectional prepregs 121, 122, 131, 132 may be illustrated. The simulation in FIG. 6 may be performed by applying a force to a specimen, which is with a plurality of unidirectional prepregs 121, 122, 131, 132 to measure a displacement in the “Z” direction. For example, in this simulation, the displacement in the “Z” direction may described be in arbitrary units, indicating that the values are relative and not tied to a specific measurement system.

Referring to FIG. 6A, the first angle θ1 of the first unidirectional prepreg 121 may be 90 degrees, the second angle θ2 of the second unidirectional prepreg 122 may be 45 degrees, the third angle θ3 of the third unidirectional prepreg 131 may be 285 degrees, and the fourth angle θ4 of the fourth unidirectional prepreg 132 may be 315 degrees. In this case, the first to fourth unidirectional prepregs 121, 122, 131, 132 may have a “saddle-shaped” warpage, in which a center portion of the unidirectional prepregs 121, 122, 131, 132 goes downward in the Z direction and a periphery portion of the unidirectional prepregs 121, 122, 131, 132 goes upward in the Z direction, and a “twist-shaped” warpage in which a periphery portion of the unidirectional prepregs 121, 122, 131, 132 goes partially up and partially down in the Z direction.

For example, at a first point P1a and a second point P1b, a displacement in the “Z” direction of the first to fourth unidirectional prepregs 121, 122, 131, 132 may be within the range of about 4.86 to about 5.69. At a third point P1c and a fourth point P1d, the displacement in the “Z” direction of the first to fourth unidirectional prepregs 121, 122, 131, 132 may be within the range of about −4.38 to about −3.54. At a fifth point P1e, the displacement in the “Z” direction of the first to fourth unidirectional prepregs 121, 122, 131, 132 may be within the range of about −0.18 to about 1.50.

Accordingly, when warpage occurs in the semiconductor package 10 and has a shape that is opposite to the saddle-shaped warpage and the twist-shaped warpage shown in FIG. 6A, the overall warpage of the semiconductor package 10 may be reduced by stacking the first to fourth unidirectional prepregs 121, 122, 131, 132 as illustrated in the stacking angles of FIG. 6A (i.e., the first angle θ1 of the first unidirectional prepreg 121 may be 90 degrees, the second angle θ2 of the second unidirectional prepreg 122 may be 45 degrees, the third angle θ3 of the third unidirectional prepreg 131 may be 285 degrees, and the fourth angle θ4 of the fourth unidirectional prepreg 132 may be 315 degrees).

Referring to FIG. 6B, the first angle θ1 of the first unidirectional prepreg 121 may be “0 degrees”, the second angle θ2 of the second unidirectional prepreg 122 may be “0 degrees”, the third angle θ3 of the third unidirectional prepreg 131 may be “0 degrees”, and the fourth angle θ4 of the fourth unidirectional prepreg 132 may be “90 degrees”. In this case, the first to fourth unidirectional prepregs 121, 122, 131, 132 may have a “smile-shaped” warpage in which a center portion of the unidirectional prepregs 121, 122, 131, 132 goes downward in the Z direction and a periphery portion of the unidirectional prepregs 121, 122, 131, 132 goes upward in the Z direction.

For example, at a first point P2a and a second point P2b, a displacement in the “Z” direction of the first to fourth unidirectional prepregs 121, 122, 131, 132 may be within the range of about 6.57 to about 7.26. At a third point P2c, the displacement in the “Z” direction of the first to fourth unidirectional prepregs 121, 122, 131, 132 may be within the range of about −0.95 to about −0.27. At and a fourth point P2d and a fifth point P2e, the displacement in the “Z” direction of the first to fourth unidirectional prepregs 121, 122, 131, 132 may be within the range of about 3.15 to about 3.85.

Accordingly, when warpage occurs in the semiconductor package 10 and has a shape that is opposite to the smile-shaped warpage shown in FIG. 6B, such as a “crying-shape” warpage, in which the center portion of the semiconductor package 10 goes upward in the Z direction and the periphery portion of the semiconductor package 10 goes downward in the Z direction, the overall warpage of the semiconductor package 10 may be reduced by stacking the first to fourth unidirectional prepregs 121, 122, 131 and 132 as illustrated in the stack angles in FIG. 6B (i.e., the first angle θ1 of the first unidirectional prepreg 121 may be “0 degrees”, the second angle θ2 of the second unidirectional prepreg 122 may be “0 degrees”, the third angle θ3 of the third unidirectional prepreg 131 may be “0 degrees”, and the fourth angle θ4 of the fourth unidirectional prepreg 132 may be “90 degrees”.

Referring to FIG. 6C, the first angle θ1 of the first unidirectional prepreg 121 may be “90 degrees”, the second angle θ2 of the second unidirectional prepreg 122 may be “0 degrees”, the third angle θ3 of the third unidirectional prepreg 131 may be “90 degrees”, and the fourth angle θ4 of the fourth unidirectional prepreg 132 may be “90 degrees”. In this case, the first to fourth unidirectional prepregs 121, 122, 131 and 132 may have a “cry-shaped” warpage in which a center portion of the unidirectional prepregs 121, 122, 131, 132 goes upward in the Z direction and a periphery portion of the unidirectional prepregs 121, 122, 131, 132 goes downward in the Z direction.

For example, at a first point P3a, a displacement in the “Z” direction of the first to fourth unidirectional prepregs 121, 122, 131, 132 may be within the range of about 0.13 to about 0.47. At a second point P3b and a third point P3c, the displacement in the “Z” direction of the first to fourth unidirectional prepregs 121, 122, 131, 132 may be within the range of about −3.63′ to about −3.29. At a fourth point P3d and a fifth point P3e, the displacement in the “Z” direction of the first to fourth unidirectional prepregs 121, 122, 131, 132 may be within the range of about −1.58 to about −1.92.

Accordingly, when warpage occurs in the semiconductor package 10 and has a shape that is opposite to the crying-shape warpage shown in FIG. 6C, such as a “smile-shape” warpage, the overall warpage of the first to fourth unidirectional prepregs 121, 122, 131, 132 may be reduced by stacking the first to fourth unidirectional prepregs 121, 122, 131, 132 as illustrated in the stack angles in FIG. 6C (i.e., the first angle θ1 of the first unidirectional prepreg 121 may be “90 degrees”, the second angle θ2 of the second unidirectional prepreg 122 may be “0 degrees”, the third angle θ3 of the third unidirectional prepreg 131 may be “90 degrees”, and the fourth angle θ4 of the fourth unidirectional prepreg 132 may be “90 degrees”).

Referring to FIG. 6D, the first angle θ1 of the first unidirectional prepreg 121 may be “315 degrees”, the second angle θ2 of the second unidirectional prepreg 122 may be “315 degrees”, the third angle θ3 of the third unidirectional prepreg 131 may be “315 degrees”, and the fourth angle θ4 of the fourth unidirectional prepreg 132 may be “45 degrees”. In this case, the first to fourth unidirectional prepregs 121, 122, 131, 132 may have a “saddle-shaped” warpage in which a center portion of the unidirectional prepregs 121, 122, 131, 132 goes downward in the Z direction and the periphery portion of the unidirectional prepregs 121, 122, 131, 132 goes upward in the Z direction.

For example, at a first point P4a, a displacement in the “Z” direction of the first to fourth unidirectional prepregs 121, 122, 131, 132 may be within the range of about 3.45 to about 5.02. At a second point P4b and a third point P4c, the displacement in the “Z” direction of the first to fourth unidirectional prepregs 121, 122, 131, 132 may be within the range of about −13.8 to about −12.23. At a fourth point P4d and a fifth point P4e, the displacement in the “Z” direction of the first to fourth unidirectional prepregs 121, 122, 131, 132 may be within the range of about −5.96 to about −4.39.

Accordingly, when warpage occurs in the semiconductor package 10 and has a shape that is opposite to the saddle-shape warpage shown in FIG. 6D, the overall warpage of the first to fourth unidirectional prepregs 121, 122, 131, 132 may be reduced by stacking the first to fourth unidirectional prepregs 121, 122, 131, 132 as illustrated in FIG. 6D (i.e., the first angle θ1 of the first unidirectional prepreg 121 may be “315 degrees”, the second angle θ2 of the second unidirectional prepreg 122 may be “315 degrees”, the third angle θ3 of the third unidirectional prepreg 131 may be “315 degrees”, and the fourth angle θ4 of the fourth unidirectional prepreg 132 may be “45 degrees”).

Referring to FIG. 6E, the first angle θ1 of the first unidirectional prepreg 121 may be “315 degrees”, the second angle θ2 of the second unidirectional prepreg 122 may be “45 degrees”, the third angle θ3 of the third unidirectional prepreg 131 may be “315 degrees”, and the fourth angle θ4 of the fourth unidirectional prepreg 132 may be “315 degrees”. In this case, the first to fourth unidirectional prepregs 121, 122, 131, 132 may have a “twist-shape” warpage in which a periphery portion of the unidirectional prepregs 121, 122, 131, 132 goes partially up and partially down in the Z direction.

For example, at a first point P5a and a second point P5b, a displacement in the “Z” direction of the first to fourth unidirectional prepregs 121, 122, 131, 132 may be within the range of about 6.57 to about 7.26. At a third point P5c, the displacement in the “Z” direction of the first to fourth unidirectional prepregs 121, 122, 131, 132 may be within the range of about −0.95 to about −0.27. At and a fourth point P5d and a fifth point P5e, the displacement in the “Z” direction of the first to fourth unidirectional prepregs 121, 122, 131, 132 may be within the range of about 3.15 to about 3.84.

Accordingly, when warpage occurs in the semiconductor package 10 and has a shape that is opposite to the twist-shape warpage shown in FIG. 6E, the overall warpage of the first to fourth unidirectional prepregs 121, 122, 131, 132 may be reduced by stacking the first to fourth unidirectional prepregs 121, 122, 131, 132 as illustrated in FIG. 6E (i.e., the first angle θ1 of the first unidirectional prepreg 121 may be “315 degrees”, the second angle θ2 of the second unidirectional prepreg 122 may be “45 degrees”, the third angle θ3 of the third unidirectional prepreg 131 may be “315 degrees”, and the fourth angle θ4 of the fourth unidirectional prepreg 132 may be “315 degrees”).

As described above, in some embodiments, the package substrate 100 of the semiconductor package 10 may include the core layer 110 having the at least one woven prepreg 111, the upper insulation layer 120 sequentially stacked on the first surface 110a of the core layer 110 and having the plurality of first prepregs 121, 122, and the lower insulation layer 130 sequentially stacked on the second surface 110b of the core layer 110 and having the plurality of second prepregs 131 and 132.

In some embodiments, the plurality of first prepregs 121, 122 and the plurality of second prepregs 132, 133 may respectively include the plurality of unidirectional fiber arrays FA1, FA2, FA3, FA4 extending in different directions. In some embodiments, each of the plurality of unidirectional fiber arrays FA1, FA2, FA3, FA4 may have a different angle (θ1, θ2, θ3, θ4) with respect to the predetermined reference extension line (CL).

Accordingly, the package substrate 100 described herein may improve the warpage of the semiconductor package 10 by combining different angles (θ1, θ2, θ3, θ4) of the unidirectional fiber arrays FA1, FA2, FA3, FA4 to induce warpage opposite to the warpage of the semiconductor package 10. Therefore, the package substrate 100 may prevent the warpage having various shapes.

Hereinafter, a package substrate 101 in accordance with example embodiments will be described.

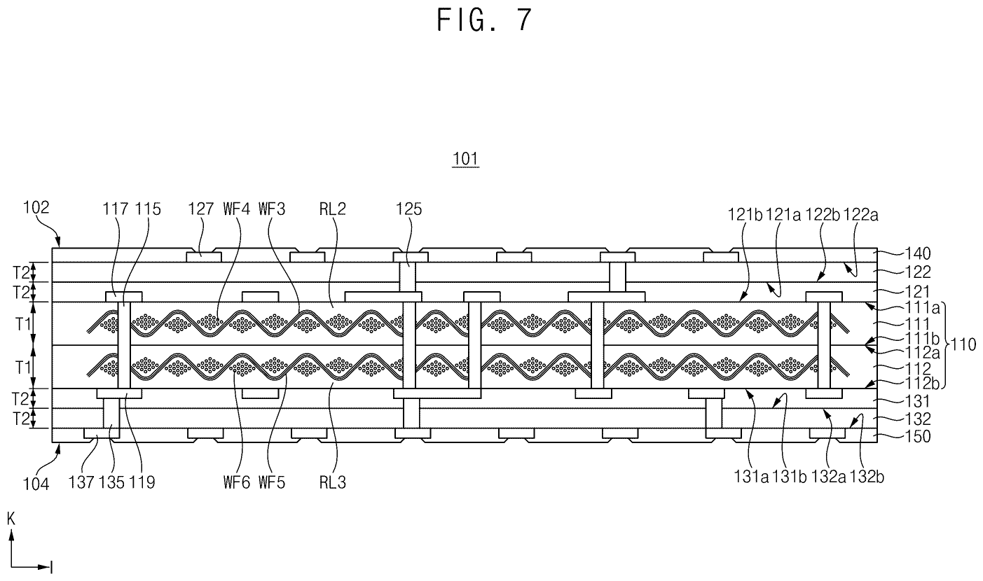

FIG. 7 is a cross-sectional side view illustrating a package substrate 101 in accordance with example embodiments.

Referring to FIG. 7, a package substrate 101 may include a core layer 110 providing a first surface 110a and a second surface 110b and having a plurality of woven prepregs, an upper insulation layer 120 having a first unidirectional prepreg 121 and a second unidirectional prepreg 122 sequentially stacked on the first surface 110a of the core layer 110, and a lower insulation layer 130 including a third unidirectional prepreg 131 and a fourth unidirectional prepreg 132 sequentially stacked on the second surface 110b of the core layer 110.

The package substrate 101 is substantially the same as the package substrate 100 and the core layer 110 described in FIGS. 1 to 6 except for the core layer 110, so repetitive description of the same components is omitted.

In some embodiments, the core layer 110 may include a first woven prepreg 112 and a second woven prepreg 113 sequentially stacked. Each of the first woven prepreg 112 and the second woven prepreg 113 may have a first thickness T1 (similar to the first thickness of the woven prepreg 111). For example, the first thickness T1 may be in the range of about 30 μm to about 40 μm.

In some embodiments, the first woven prepreg 112 may include a plurality of third woven fiber arrays WF3 and a plurality of fourth woven fiber arrays WF4, which intersect and/or overlap each other, and a second resin layer RL2 surrounding the plurality of third woven fiber arrays WF3 and the plurality of fourth woven fiber arrays WF4. The second woven prepreg 113 may include a plurality of fifth woven fiber arrays WF5 and a plurality of sixth woven fiber arrays WF6, which intersect and/or overlap each other, and a third resin layer RL3 surrounding the plurality of fifth woven fiber arrays WF5 and the plurality of sixth woven fiber arrays WF6.

In some embodiments, the plurality of third woven fiber arrays WF3 and the plurality of fifth woven fiber arrays WF5 may extend in a first horizontal direction (I direction), and the plurality of fourth woven fiber arrays WF4 and the plurality of sixth woven fiber arrays WF6 may extend in a second horizontal direction (J direction).

For example, in some embodiments, each of the plurality of third to sixth woven fiber arrays WF3, WF4, WF5, WF6 may include a plurality of fiber filaments adjacent to each other. In some embodiments, the plurality of third to sixth woven fiber arrays WF3, WF4, WF5, WF6 may include reinforcement fibers such as glass fibers, carbon fibers, etc. Further, in some embodiments, the second and third resin layers RL2, RL3 may include a thermosetting material such as an epoxy resin, etc.

While the figures illustrate that the core layer 110 include the first and second woven prepregs 112, 113, it will be appreciated that this is exemplary, so the present inventive concept is not limited thereto. Accordingly, the number of the first and second woven prepregs 112, 113 may be varied.

The semiconductor package 10 described herein may include semiconductor devices such as logic devices or memory devices. The semiconductor package 10 may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A package substrate, comprising:
a core layer providing a first surface and an opposing second surface, the core layer comprising at least one woven prepreg having a plurality of woven fiber arrays at least partially overlapping each other;
an upper insulation layer comprising a first unidirectional prepreg and a second unidirectional prepreg sequentially stacked on the first surface of the core layer;
a lower insulation layer comprising a third unidirectional prepreg and a fourth unidirectional prepreg sequentially stacked on the second surface of the core layer; and
a plurality of inner wirings in the core layer, the upper insulation layer, and the lower insulation layer and electrically connected to each other,
wherein the first unidirectional prepreg comprises a plurality of first unidirectional fiber arrays having a first angle relative to a first direction, and the second unidirectional prepreg comprises a plurality of second unidirectional fiber arrays having a second angle relative to the first direction, and
wherein the third unidirectional prepreg comprises a plurality of third unidirectional fiber arrays having a third angle relative to the first direction, and the fourth unidirectional prepreg comprises a plurality of fourth unidirectional fiber arrays having a fourth angle relative to the first direction.

2. The package substrate of claim 1, wherein the first angle, the second angle, the third angle, and the fourth angle are different from each other.

3. The package substrate of claim 1, wherein the first angle, the second angle, and the third angle are equal to each other.

4. The package substrate of claim 1, wherein the first angle, the third angle, and the fourth angle are equal to each other.

5. The package substrate of claim 1, wherein the at least one woven prepreg has a first thickness, and the first unidirectional prepreg, the second unidirectional prepreg, the third unidirectional prepreg, and the fourth unidirectional prepreg have a second thickness less than the first thickness.

6. The package substrate of claim 1, wherein the at least one woven prepreg comprises a first woven prepreg and a second woven prepreg sequentially stacked, and
wherein the first woven prepreg comprises a plurality of first woven fiber arrays at least partially overlapping each other, and the second woven prepreg comprises a plurality of second fiber arrays at least partially overlapping each other.

7. The package substrate of claim 1, wherein the at least one woven prepreg comprises a plurality of first woven fiber arrays extending in a second direction and a plurality of second woven fiber arrays extending in a third direction perpendicular to the second direction, and
wherein the first direction is parallel with at least one of the second direction and/or the third direction.

8. The package substrate of claim 1, wherein the plurality of inner wirings comprises,
a plurality of conductive connection members in the core layer;
a plurality of upper wirings in the upper insulation layer and electrically connected to the plurality of conductive connection members; and
a plurality of lower wirings in the lower insulation layer and electrically connected to the plurality of conductive connection members.

9. A package substrate, comprising:
a core layer providing a first surface and an opposing second surface, the core layer comprising at least one woven prepreg having a plurality of woven fiber arrays at least partially overlapping each other;
a plurality of conductive connection members comprising a plurality of first inner wirings in the core layer, a plurality of first upper wirings on the first surface of the core layer, and a plurality of first lower wirings on the second surface of the core layer;
an upper insulation layer comprising a first unidirectional prepreg and a second unidirectional prepreg sequentially stacked on the first surface of the core layer;
a plurality of second inner wirings in the upper insulation layer and electrically connected to the plurality of conductive connection members;
a lower insulation layer comprising a third unidirectional prepreg and a fourth unidirectional prepreg sequentially stacked on the second surface of the core layer; and
a plurality of third inner wirings in the lower insulation layer and electrically connected to the conductive connection members,
wherein the first unidirectional prepreg comprises a plurality of first unidirectional fiber arrays having a first angle relative to a first direction, and the second unidirectional prepreg comprises a plurality of second unidirectional fiber arrays having a second angle relative to the first direction, and
wherein the third unidirectional prepreg comprises a plurality of third unidirectional fiber arrays having a third angle relative to the first direction, and the fourth unidirectional prepreg comprises a plurality of fourth unidirectional fiber arrays having a fourth angle relative to the first direction.

10. The package substrate of claim 9, wherein the first angle, the second angle, the third angle, and the fourth angle are different from each other.

11. The package substrate of claim 9, wherein the first angle, the second angle, and the third angle are equal to each other.

12. The package substrate of claim 9, wherein the first angle, the third angle, and the fourth angle are equal to each other.

13. The package substrate of claim 9, further comprising:
a plurality of upper substrate pads respectively on the plurality of second inner wirings;
an upper cover layer on the upper insulation layer to expose at least a portion of each of the plurality of upper substrate pads;
a plurality of lower substrate pads on the plurality of third inner wirings; and
a lower cover layer on the lower insulation layer to expose at least a portion of each of the plurality of lower substrate pads.

14. A semiconductor package, comprising:
a package substrate comprising a core layer providing at least one woven prepreg that has a plurality of woven fiber arrays, an upper insulation layer comprising a plurality of upper prepregs sequentially stacked on a first surface of the core layer and, a lower insulation layer comprising a plurality of lower prepregs sequentially stacked on a second surface of the core layer opposite to the first surface of the core layer, a plurality of inner wirings in the package substrate and electrically connected to each other, a plurality of upper substrate pads electrically connected to the plurality of inner wirings, and a plurality of lower substrate pads electrically connected to the plurality of inner wirings;
at least one semiconductor chip mounted on the package substrate; and
a molding member on the package substrate to cover at least a portion of the at least one semiconductor chip,
wherein the plurality of upper prepregs comprises a first unidirectional prepreg having a plurality of first unidirectional fiber arrays having a first angle relative to a first direction and a second unidirectional prepreg having a plurality of second unidirectional fiber arrays having a second angle relative to the first direction, and
wherein the plurality of lower prepregs comprises a third unidirectional prepreg having a plurality of third unidirectional fiber arrays having a third angle relative to the first direction and a fourth unidirectional prepreg comprises a fourth unidirectional prepreg having a plurality of fourth unidirectional fiber arrays having a fourth angle relative to the first direction.

15. The semiconductor package of claim 14, wherein the first angle, the second angle, the third angle, and the fourth angle are different from each other.

16. The semiconductor package of claim 14, wherein the first angle, the second angle, and the third angle are equal to each other.

17. The semiconductor package of claim 14, wherein the first angle, the third angle, and the fourth angle are equal to each other.

18. The semiconductor package of claim 14, wherein the at least one woven prepreg has a first thickness, and the first unidirectional prepreg, the second unidirectional prepreg, the third unidirectional prepreg, and the fourth unidirectional prepreg have a second thickness less than the first thickness.

19. The semiconductor package of claim 14, wherein the at least one woven prepreg comprises a plurality of first woven fiber arrays extending in a second direction and a plurality of second woven fiber arrays extending in a third direction perpendicular to the second direction,
wherein the first direction is parallel with at least one of the second direction and/or the third direction.

20. The semiconductor package of claim 14, wherein the package substrate comprises a plurality of external connection members respectively on the plurality of lower substrate pads.
